(19) United States
(12) Patent Application Publication
(10) Pub. No.: US 2026/0339374 A1
(43) Pub. Date: Oct. 29, 2026

(54) VOLTAGE REFERENCE WITH SELF-BIASED TRIM CIRCUITRY

(71) Applicant: Microchip Technology Incorporated, Chandler, AZ (US)

(72) Inventors: Prasula Thotton Veedu, Chennai (IN); Brian Cherek, Colorado Springs, CO (US)

(73) Assignee: Microchip Technology Incorporated, Chandler, AZ (US)

(21) Appl. No.: 19/269,796

(22) Filed: Jul. 15, 2025

(30) Foreign Application Priority Data
Apr. 24, 2025 (IN) 202511039496

(51) Int. Cl. G05F 3/26; G11C 5/14

(52) U.S. Cl. CPC G05F 3/267; G11C 5/147

(57) ABSTRACT

An integrated circuit component includes voltage reference circuitry. The voltage reference circuitry is tuned to be relatively insensitive to temperature changes. However, due to process variations, the bandgap voltage reference circuitry in the voltage reference circuitry may have a larger output variation and larger output voltage temperature dependence than desired. In order to reduce the dependence, programmable trim circuitry can redirect some of the current passing through the transistors of the bandgap voltage reference circuitry, trimming the bandgap voltage reference circuitry to have reduced output voltage variation and reduced temperature dependence.

### CROSS-REFERENCE TO RELATED APPLICATIONS

This application claims the benefit under 35 U.S.C. § 119(a) of Indian Provisional Patent Application Serial No. 202511039496, filed Apr. 24, 2025, entitled “VOLTAGE REFERENCE WITH SELF-BIASED TRIM CIRCUITRY,” the entirety of which application is incorporated by reference herein.

### TECHNICAL FIELD

The present disclosure relates generally to a voltage reference, and more specifically to a voltage reference with trim circuitry that can be self-biased.

### BACKGROUND

Bandgap voltage references exploit the complementary temperature coefficients of a bipolar transistor's base-emitter voltage (V_{BE}, which falls by roughly 2 mV/°C.) and a scaled thermal voltage (V_{T}=kT/q, which rises by about 0.085 mV/°C.) to produce a nearly temperature-independent reference. By combining a “proportional-to-absolute-temperature” (PTAT) voltage with V_{BE}, the reference cancels first-order temperature drift. However, mismatches in transistor emitter-area ratios, resistor tolerances, current-gain (β) variability, and saturation current variability across process corners introduce offset errors and curvature that should be trimmed or compensated.

### SUMMARY OF THE INVENTION

Aspects of various examples include using a fraction of the PTAT current created by the bandgap core to provide a reference to a programmable current trim circuitry. Depending upon the magnitude and polarity of the voltage error, a correction current from this programmable current trim circuitry is fed into specific nodes in the bandgap core to reduce the error. By using PTAT current for correction, the error caused by process variations is reduced.

### BRIEF DESCRIPTION OF THE DRAWINGS

FIG. 1 illustrates an example circuit with a bandgap voltage reference and programmable trim circuitry.

FIG. 2 illustrates various examples of reference voltage as a function of temperature before trimming.

FIG. 3 illustrates various examples of reference voltage as a function of temperature before and after trimming.

FIG. 4 illustrates various examples of reference voltage as a function of temperature after trimming.

FIG. 5 illustrates an example integrated circuit device that may include one or more components in accordance with examples disclosed herein.

FIG. 6 is a simplified block diagram of at least one example of a compute device that may include the circuit of FIG. 1.

### DETAILED DESCRIPTION

In various examples, significant variations in bandgap voltage of a bandgap voltage reference may occur across process corners. The root cause may be due to, e.g., variation in both the DC current gain β and the saturation current I_{S} of the PNP transistors across process corners. Variations in the PNP electrical characteristics may cause V_{BE} variations, which in turn may cause V_{BG} voltage variations. The PNP variation affects not only the magnitude of the bandgap voltage but also alters the temperature coefficient. Due to the effects of process variation (as well as offset variations of the operational amplifier), the V_{BG} voltage may have, e.g., a ±3% variation in production. Techniques disclosed herein can reduce the impact of the process-induced V_{BE} variation of the bandgap voltage, reducing the post-trim error to, e.g., ±1% in various examples. In other examples, the post-trim error may be reduced further by, e.g., using a higher-resolution digital-to-analog converter (DAC) for trimming.

In the following description, specific details are set forth, but examples of the technologies described herein may be practiced without these specific details. Well-known circuits, structures, and techniques have not been shown in detail to avoid obscuring an understanding of this description. Phrases such as “an example,” “various examples,” “some examples,” and the like may include features, structures, or characteristics, but not every example necessarily includes the particular features, structures, or characteristics.

Some examples may have some, all, or none of the features described for other examples. “First,” “second,” “third,” and the like describe a common object and indicate different instances of like objects being referred to. Such adjectives do not imply objects so described must be in a given sequence, either temporally or spatially, in ranking, or any other manner.

“Connected” may indicate elements are in direct physical or electrical contact with each other and “coupled” may indicate elements cooperate or interact with each other, but they may or may not be in direct physical or electrical contact. Furthermore, the terms “comprising,” “including,” “having,” and the like, as used with respect to examples of the present disclosure, are synonymous.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y. As used herein, a die may be considered to be adjacent a substrate if there are no layers or components between the die and the substrate, although there can be pads, solder balls, etc., between the substrate and the die, with the die and the substrate still considered to be adjacent. As used herein, the phrase “electrically coupled” refers to the presence of one or more electrically conductive paths between components that are recited as being electrically coupled.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation, location, or both orientation and location of layers, components, portions of components, etc., within a consistent but arbitrary frame of reference, which is made clear by reference to the text and the associated Figures describing the layers, component, portions of components, etc. under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

As used herein, the term “electronic component” can refer to an active electronic component (e.g., processing unit, memory, storage device, transistor) or a passive electronic component (e.g., resistor, inductor, capacitor).

As used herein, the terms “operating,” “executing,” or “running” as they pertain to software or firmware in relation to a system, device, platform, or resource are used interchangeably and can refer to software or firmware stored in one or more computer-readable storage media accessible by the system, device, platform or resource, even though the software or firmware instructions are not actively being executed by the system, device, platform, or resource.

Reference is now made to the drawings, which are not necessarily drawn to scale, wherein similar or the same numbers may be used to designate the same or similar parts in different figures. The use of similar or the same numbers in different figures does not mean all figures including similar or the same numbers constitute a single or same example. Like numerals having different letter suffixes may represent different instances of similar components. The drawings illustrate generally, by way of example, but not by way of limitation, various examples discussed in the present document.

In the following description, for purposes of explanation, numerous specific details are set forth in order to provide a thorough understanding thereof. It may be evident, however, that the novel examples can be practiced without these specific details. In other instances, well-known structures and devices are shown in block diagram form in order to facilitate a description thereof. The intention is to cover all modifications, equivalents, and alternatives within the scope of the claims.

As used in this application and the claims, a list of items joined by the term “and/or” can mean any combination of the listed items. For example, the phrase “A, B, and/or C” can mean A; B; C; A and B; A and C; B and C; or A, B and C. As used in this application and the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B, and C” can mean A; B; C; A and B; A and C; B and C; or A, B, and C.

As used in this application and the claims, the phrase “individual of” or “respective of” followed by a list of items recited or stated as having a trait, feature, etc., means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises a sidewall, and C comprises a sidewall.

The disclosed methods, apparatuses, and systems are not to be construed as limiting in any way. Instead, the present disclosure is directed toward all novel and nonobvious features and aspects of the various disclosed examples, alone and in various combinations and subcombinations with one another. The disclosed methods, apparatuses, and systems are not limited to any specific aspect or feature or combination thereof, nor do the disclosed examples require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

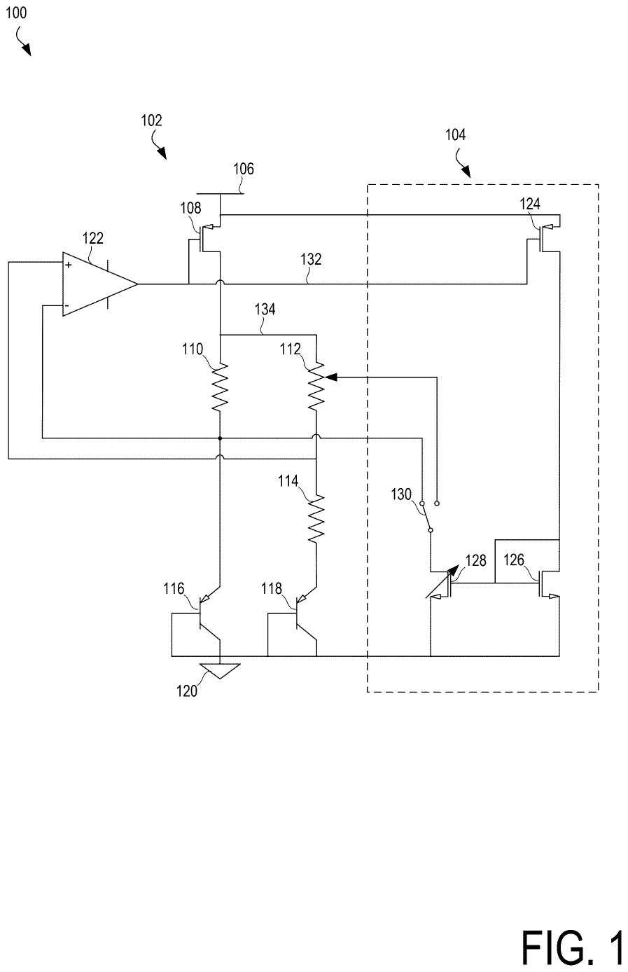

Referring now to FIG. 1, in one example, a temperature-insensitive voltage reference circuit 100 for an integrated circuit component includes bandgap voltage reference circuitry 102 and bandgap voltage reference trim circuitry 104. The bandgap voltage reference circuitry 102 includes a voltage source 106, a MOSFET transistor 108, resistors 110, 112, 114, bipolar junction transistors (BJTs) 116, 118, ground 120, and an operation amplifier (op amp) 122. In one example, the circuit node 134 at the junction of resistors 110, 112 is the reference voltage produced by the bandgap voltage reference circuitry 102. The bandgap voltage reference trim circuitry 104 includes a MOSFET 124, one or more MOSFETs 126, a programmable array of MOSFETs 128, and a programmable switch 130. In use, the voltage difference between the two transistors 116, 118, operated at different current densities, is used to generate a current that is proportional to absolute temperature (PTAT) in a resistor. The change in V_{BE} of one transistor as a function of temperature has a sign that is the opposite of that of the PTAT, so with proper scaling, the sum of the two is approximately insensitive to temperature and can be used as a voltage reference that is not very temperature sensitive. In order to balance the positive and negative change in the output voltage, two parameters can be tuned: the ratio of the emitter area of the transistor 118 to that of the transistor 116, and the ratio of the resistor 114 to the resistor 112. In one embodiment, the transistor 118 may have 24 times the emitter area of the transistor 116, the resistor 112 may have a resistance of 1 megaohm, the resistor 114 may have a resistance of 258 kiloohm, and the resistor 110 may have a resistance of 200 kiloohm.

However, the bandgap voltage reference circuitry 102 is susceptible to various process variations. For example, the op amp 122 may have a slight offset voltage between the inputs, the transistors 116, 118 may have process variations, etc. In order to trim the bandgap voltage reference circuitry 102 to compensate for the process variations, in various examples, a fraction of the PTAT current created by the bandgap core is provided to a current DAC formed by the transistors 128. Depending upon the magnitude and polarity of the voltage error at calibration time, a correction current is drawn from specific nodes in the bandgap core into the DAC in order to mitigate the error. By using PTAT current for correction, the error caused by PNP variation in the transistors 116, 118 is reduced. This approach corrects for the PNP variations in the transistors 116, 118 frequently found in advanced CMOS processes by feeding back a portion of the current already available within the circuit, without the need for additional analog circuitry.

In one example, the one or more transistors 126 is an array of 6 transistors, and the array of transistors 128 includes 16 transistors. In one example, the 16 transistors can be turned on one at a time, using a binary-to-thermometer decoder. A four-bit register stores a number indicating how many of the 16 transistors should be activated. A thermometer decoder is used to ensure the current that is redirected increases monotonically and approximately linearly with the number stored in the register. An additional bit in a register is used to control a state of the switch 130, controlling whether the voltage is trimmed higher or lower. The register may be embodied as, e.g., programmable fuses, programmable non-volatile memory, etc.

If, during calibration, the voltage is too high, a portion of the current flowing through the resistor 110 is directed to the current DAC by turning on a suitable number of the transistors 128, reducing the current in the transistor 116. In this case, the switch 130 is configured as shown in FIG. 1. The redirection of the current causes both the V_{BE} across the transistor 116 (V_{BE1}) and the difference in V_{BE} between the two transistors 116, 118 (ΔV_{BE}) to drop, resulting in a lower output voltage 132 from the op amp 122 and a more negative temperature coefficient for the output 134. If, during calibration, the voltage is too low, the core current from the DAC is pulled from a fraction of the resistor 112 by changing the state of the switch 130 and turning on a suitable number of the transistors 128. The tap off point in the resistor 112 may be at about, e.g., 80-95%, or about 10%, of the resistance of the resistor 112. This increases the output voltage 134 due to the increased IR drop across the resistor 112, which also increases the current into the transistor 116, slightly increasing ΔV_{be}. Consequently, the output voltage 134 will have a higher value and a more positive temperature coefficient. In either case, the suitable number of transistors 128 to turn on and the state of the switch 130 are stored in a register and accessed when the bandgap voltage reference circuitry 102 is powered on. In some examples, the bandgap voltage reference circuitry 102 may be designed to almost always be higher (or lower) than the target voltage, and trimming may be done in one direction only, which may simplify the trim circuitry. In some cases, the bandgap voltage reference trim circuitry 104 may be designed to switch between pulling current that would otherwise flow through the transistor 116 (as shown in FIG. 1) or adding additional current through the transistor 116, rather than switching between pulling current from the resistor 110 or the resistor 112.

As a result of this approach, the impact of process variation can be significantly reduced. This approach corrects the variations in the output voltage 134 caused by the process (V_{BE} variation in the transistors 116, 118 and device mismatch in the operational amplifier), reducing the post-trim error to ±1%, in various examples. This approach allows for low operating current, no additional analog components required except a 4-bit DAC, no additional biasing circuitry, and a small area impact (about 7%, in various examples).

The bandgap is the heart of the analog sub-system. It is used to determine the primary reference voltages to operate that system. It provides multiple voltages to the timing and security circuitry of the system. Reduced bandgap variation directly translates to improved performance in all aspects of the rest of the system. Conversely, a tighter bandgap voltage allows for relaxed design requirements of the other blocks for a given system error budget. In various examples, the trimming capability allows for adjusting the bandgap voltage by ±6% in 0.5% increments in discrete steps.

The temperature-insensitive voltage reference circuit 100 may be integrated into any suitable component. The temperature-insensitive reference voltage architecture is particularly valuable in applications requiring high precision across wide operating temperature ranges, such as industrial automation, automotive electronics, and medical devices. For instance, in industrial control systems, stable reference voltages ensure accurate sensor readings and reliable actuator control despite environmental fluctuations. In automotive applications, the reference voltage supports critical functions like engine management, battery monitoring, and safety systems, where thermal stability is essential for compliance with stringent safety standards. Similarly, in medical devices—such as implantable monitors or diagnostic equipment—the reference voltage enables consistent performance in varying patient conditions, reducing the risk of measurement errors. Additionally, the trimming capability enhances adaptability for custom design requirements, allowing manufacturers to optimize system performance without compromising reliability. By decoupling reference voltage accuracy from temperature drift, this innovation also simplifies system-level calibration, reduces power consumption in compensation circuits, and extends the operational lifespan of analog subsystems in harsh or unpredictable environments.

In some examples, the design of the temperature-insensitive voltage reference circuit 100 can provide additional security benefits. For example, an attacker may try to take the supply voltage low or exceed a die threshold temperature and break the chip before it enters a power on reset state, but a circuit with low headroom will make such an attach more difficult. For example, the voltage source 106 may be, e.g., 1.3 volts with a bandgap of the transistors 116, 118 of 1.2 volts.

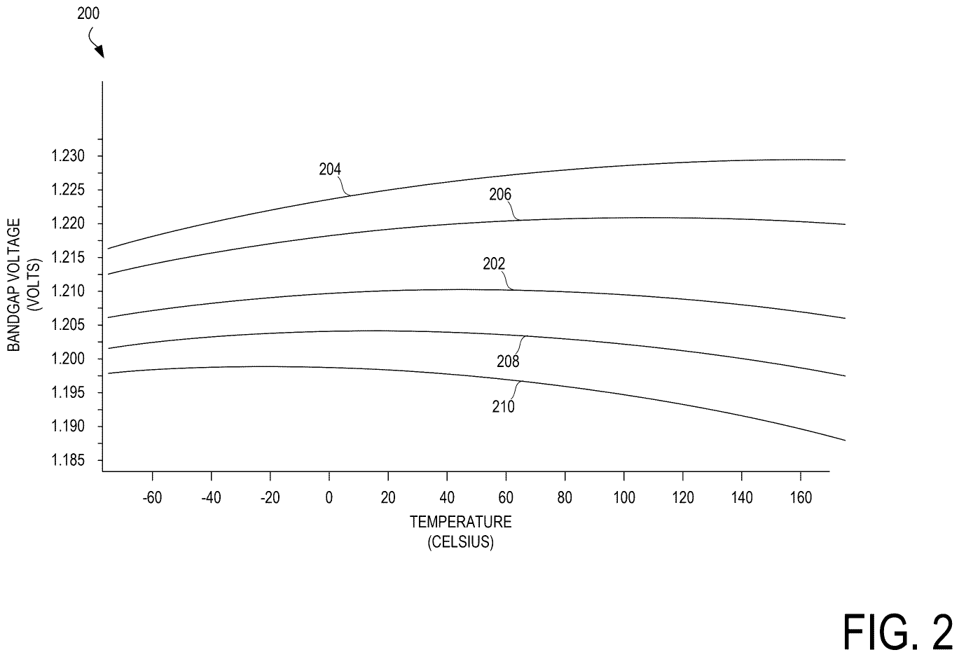

Referring now to FIG. 2, in various example, a plot 200 shows a nominal voltage-temperature curve 202 for the bandgap voltage reference circuitry 102, along with curves 204, 206, 208, 210 for various examples in various process corners, without trimming from the bandgap voltage reference trim circuitry 104.

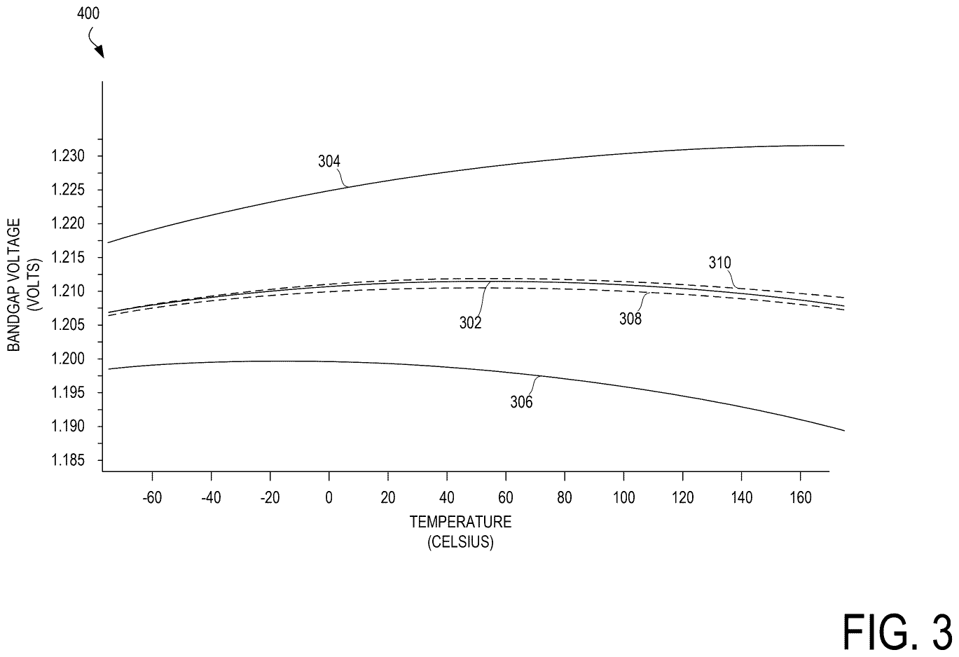

Referring now to FIG. 3, in various examples, a plot 300 shows a nominal voltage-temperature curve 302 for the bandgap voltage reference circuitry 102. The plot also shows pre-trim curves 304, 306 from two possible process corners as well as corresponding post-trim curves 308, 310 from the same process corners. As can be seen from the plot, the post-trim curves 308, 310 are significantly closer to the nominal curve 302 compared to the pre-trim curves 304, 306.

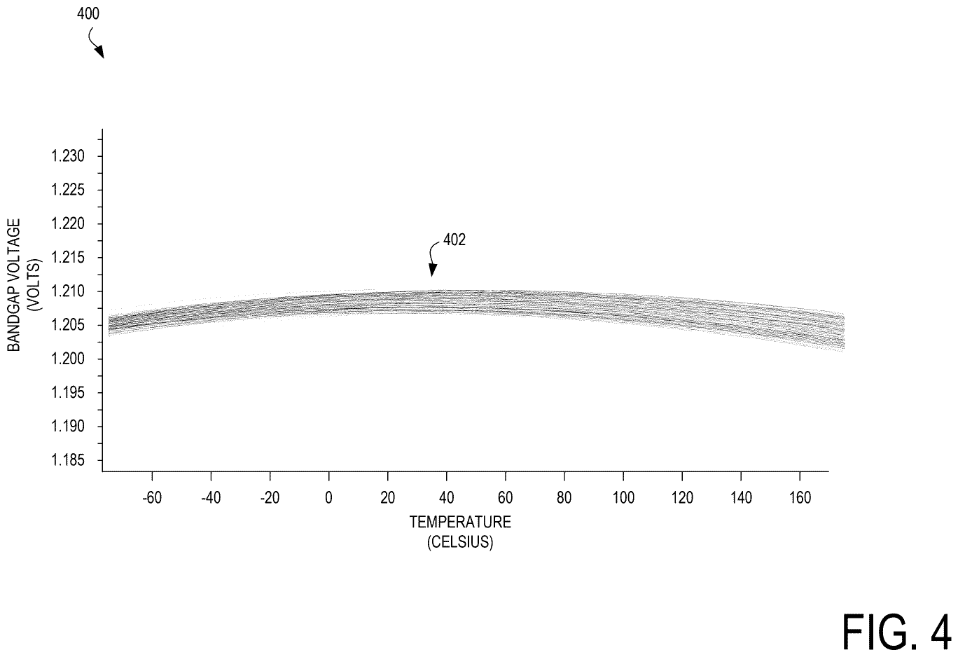

Referring now to FIG. 4, in various examples, a plot 400 shows curves 402 from various examples for simulated voltage-temperature curves post-trim. The curves 402 are tightly grouped around the nominal curve shown in FIG. 4.

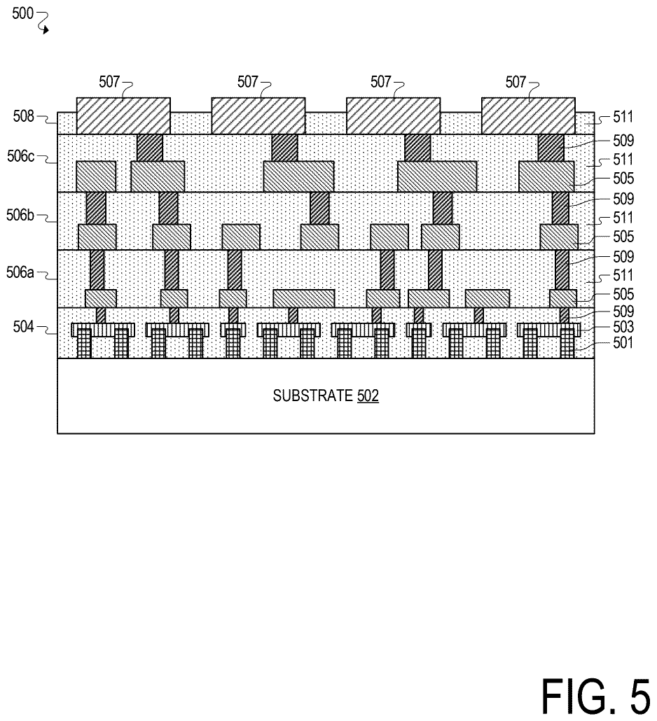

Referring now to FIG. 5, in one example, an integrated circuit (IC) device 500 is shown. The IC device 500 may include temperature-insensitive voltage reference circuits 100 in accordance with examples disclosed herein. In some examples, IC device 500 may be included in an IC die, such as a system-on-chip (SoC) die, processor die, memory die, input/output (I/O) die, or power die (e.g., power management integrated circuit (PMIC)), among other examples.

In the illustrated example, IC device 500 includes a semiconductor substrate 502, a device layer 504 over the semiconductor substrate 502, multiple internal interconnect layers 506a-c over the device layer 504, and an external interconnect layer 508 over the internal interconnect layers 506a-c (e.g., on the upper surface of IC device 500).

The semiconductor substrate 502 may include any suitable semiconductor material, including, without limitation, silicon, silicon carbide, silicon germanium, germanium, indium antimonide, lead telluride, indium arsenide, indium phosphide, gallium arsenide, gallium antimonide, or other group II-VI, III-V, or IV semiconductor materials.

The device layer 504 may include one or more semiconductor devices 501 (e.g., transistors, diodes) formed in, on, or over the semiconductor substrate 502. In some examples, the semiconductor devices 501 may include, without limitation, bipolar junction transistors (BJTs), field-effect transistors (FETs), junction field-effect transistors (JFETs), metal-oxide-semiconductor field-effect transistors (MOSFETs), double-diffused metal-oxide-semiconductor (DMOS) transistors, laterally-diffused metal-oxide-semiconductor (LDMOS) transistors, complementary metal-oxide-semiconductor (CMOS) transistors (e.g., n-type MOS (NMOS) transistors, p-type MOS (PMOS) transistors), bipolar diodes (e.g., p-n junction diodes), unipolar diodes (e.g., metal-semiconductor junction (Schottky) diodes), bipolar-CMOS-DMOS (BCD) devices (e.g., integrated BJT, CMOS, and DMOS/LDMOS transistors on a single chip for mixed-signal (analog/digital) high-power applications), or combinations thereof.

In some examples, the semiconductor devices 501 may include n-type semiconductor devices (e.g., NMOS transistors), p-type semiconductor devices (e.g., PMOS transistors), or a combination thereof.

The device layer 504 also includes conductive contacts 503 on the semiconductor devices 501 (e.g., a source, drain, or gate contact 503 coupled to the source, drain, or gate of a transistor 501), which are electrically coupled to the internal interconnect layers 506 by vias 509.

The internal interconnect layers 506a-c include conductive features 505, such as traces or pads, embedded in dielectric material 511 (e.g., dielectric buildup material such as Ajinomoto Build-Up Film (ABF)). The conductive features 505 in different interconnect layers 506a-c are electrically coupled to each other by vias 509.

The external interconnect layer 508 includes conductive contacts 507 (e.g., pads) embedded in dielectric material 511 (e.g., solder resist) on the upper surface of IC device 500. The conductive contacts 511 are electrically coupled to the internal interconnect layers 506 by vias 509. Moreover, the conductive contacts 511 can be used to electrically couple IC device 500 to another external IC device (not shown), such as an IC die, IC package, or circuit board (e.g., PCB).

The conductive features 503, 505, 507 in different layers 504, 506a-c, 508 of IC device 500 are electrically coupled to each other by vias 509. Moreover, all of the conductive features 503, 505, 507, 509 in IC device 500 may be collectively referred to as conductive routing. The conductive routing 503, 505, 507, 509 may be used to route power or signals to, from, or between semiconductor devices 501 in the device layer 504 and any external IC devices electrically coupled to the surface contacts 507.

Although a certain number of internal interconnect layers 506a-c are shown in the illustrated example, IC device 500 may include any suitable number of interconnect layers 506. In some implementations, interconnect layers 506 that are higher up in the device stack (e.g., further from the device layer 504) may be thicker than interconnect layers 506 that are lower in the device stack. In some instances, interconnect layers 506a-c may be referred to as metal layers or metallization layers. As an example, interconnect layer 506 a may be referred to as the metal 0 (M0) layer, interconnect layer 506b may be referred to as the metal 1 (M1) layer, and interconnect layer 506c may be referred to as the metal 2 (M2) layer.

The dielectric material 511 in the device layer 504, the internal interconnect layers 506, and the external interconnect layer 508 may vary across the respective layers. Moreover, the conductive features 503, 505, 507, 509 in IC device 500 may be formed of any suitable conductive materials (e.g., metal).

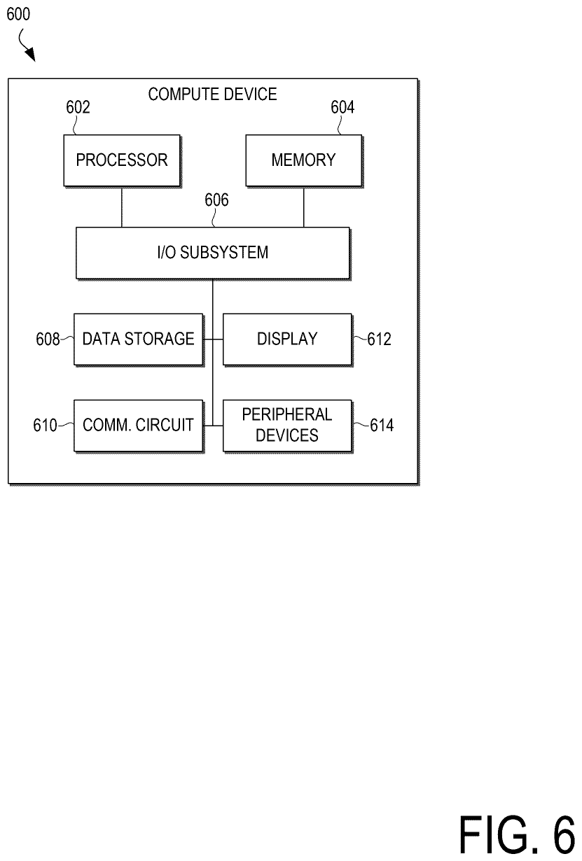

Referring now to FIG. 6, in one example, a block diagram of a compute device 600 shows various components of the computing device 600. The compute device 600 may include any suitable examples of the temperature-insensitive voltage reference circuit 100 disclosed herein. For example, the compute device 600 or any suitable component thereof may use the temperature-insensitive voltage reference circuit 100 as a voltage reference for various analog or digital circuitry.

The compute device 600 may be embodied as any type of compute device. For example, the compute device 600 may be embodied as or otherwise be included in, without limitation, a server computer, an embedded computing system, a System-on-a-Chip (SoC), a multiprocessor system, a processor-based system, a consumer electronic device, a smartphone, a cellular phone, a desktop computer, a tablet computer, a notebook computer, a laptop computer, a network device, a router, a switch, a networked computer, a wearable computer, a handset, a messaging device, a camera device, an application-specific integrated circuit (ASIC), a field-programmable gate array (FPGA), or any other computing device.

The illustrative compute device 600 includes one or more processors 602, a memory 604, an input/output (I/O) subsystem 606, data storage 608, a communication circuit 610, a display 612, and one or more peripheral devices 614. In various examples, one or more of the illustrative components of the compute device 600 may be incorporated in, or otherwise form a portion of, another component. For example, the memory 604, or portions thereof, may be incorporated in the processor 602 in various examples. In various examples, one or more of the illustrative components may be physically separated from another component. In some examples, some of the components in the illustrative compute device 600 may be omitted.

The processor 602 may be embodied as any type of processor capable of performing the functions described herein. For example, the processor 602 may be embodied as a single or multi-core processor(s), a single or multi-socket processor, a digital signal processor, a graphics processor, a neural network compute engine, an image processor, a microcontroller, or other processor or processing/controlling circuit. Similarly, the memory 604 may be embodied as any type of volatile or non-volatile memory or data storage capable of performing the functions described herein. In operation, the memory 604 may store various data and software used during operation of the compute device 600 such as operating systems, applications, programs, libraries, and drivers. The memory 604 is communicatively coupled to the processor 602 via the I/O subsystem 606, which may be embodied as circuitry, components, or both to facilitate input/output operations with the processor 602, the memory 604, and other components of the compute device 600. For example, the I/O subsystem 606 may be embodied as, or otherwise include, memory controller hubs, input/output control hubs, firmware devices, communication links (e.g., without limitation, point-to-point links, bus links, wires, cables, light guides, or printed circuit board traces), other components and subsystems to facilitate the input/output operations. The I/O subsystem 606 may connect various internal and external components of the compute device 600 to each other with use of, without limitation, any suitable connector, interconnect, bus, or protocol, such as an SoC fabric, PCIe®, USB2, USB3, USB4, NVMe®, Thunderbolt®, or the like. In various examples, the I/O subsystem 606 may form a portion of a system-on-a-chip (SoC) and be incorporated, along with the processor 602, the memory 604, and other components of the compute device 600 on a single integrated circuit chip.

The data storage 608 may be embodied as any type of device or devices configured for the short-term or long-term storage of data. For example, the data storage 608 may include any one or more memory devices and circuits, memory cards, hard disk drives, solid-state drives, or other data storage devices.

The communication circuit 610 may be embodied as any type of interface capable of interfacing the compute device 600 with other compute devices, such as over one or more wired or wireless connections. In various examples, the communication circuit 610 may be capable of interfacing with any appropriate cable type, such as an electrical cable or an optical cable. The communication circuit 610 may be configured to use any one or more communication technology and associated protocols (e.g., without limitation, Ethernet, Bluetooth®, Wi-Fi®, WiMAX, or near field communication (NFC)). The communication circuit 610 may be located on silicon separate from the processor 602, or the communication circuit 610 may be included in a multi-chip package with the processor 602, or even on the same die as the processor 602. The communication circuit 610 may be embodied as one or more add-in-boards, daughtercards, network interface cards, controller chips, chipsets, specialized components such as a field-programmable gate array (FPGA) or application-specific integrated circuit (ASIC), or other devices that may be used by the compute device 600 to connect with another compute device. In various examples, communication circuit 610 may be embodied as part of a system-on-a-chip (SoC) that includes one or more processors or may be included on a multichip package that also contains one or more processors. In various examples, the communication circuit 610 may include a local processor (not shown) or a local memory (not shown) or both that are both local to the communication circuit 610. In such examples, the local processor of the communication circuit 610 may be capable of performing one or more of the functions of the processor 602 described herein. Additionally or alternatively, in such examples, the local memory of the communication circuit 610 may be integrated into one or more components of the compute device 600 at the board level, socket level, chip level, or other levels.

The display 612 may be embodied as any type of display on which information may be displayed to a user of the compute device 600, such as a touchscreen display, a liquid crystal display (LCD), a thin film transistor LCD (TFT-LCD), a light-emitting diode (LED) display, an organic light-emitting diode (OLED) display, a cathode ray tube (CRT) display, a plasma display, an image projector (e.g., 2D or 3D), a laser projector, a heads-up display, or other display technology.

In various examples, the compute device 600 may include other or additional components, such as those commonly found in a compute device. For example, the compute device 600 may also have peripheral devices 614, such as, without limitation, a keyboard, a mouse, or an external storage device. In various examples, the compute device 600 may be connected to a dock that can interface with various devices, including peripheral devices 614.

### EXAMPLES

Illustrative examples of the technologies disclosed herein are provided below. An example of the technologies may include any one or more, and any combination of, the examples described below.

Example 1 includes an integrated circuit component comprising bandgap voltage reference circuitry comprising a current source to provide current; and bandgap voltage reference trim circuitry comprising programmable circuitry to redirect some of the current provided by the current source from the bandgap voltage reference circuitry to the bandgap voltage reference trim circuitry.

Example 2 includes the subject matter of Example 1, and further including a current mirror, the current mirror comprising a first transistor and a second transistor, wherein an output of an operational amplifier is connected to a gate of the first transistor and a gate of the second transistor.

Example 3 includes the subject matter of any of Examples 1 and 2, and wherein the bandgap voltage reference circuitry comprises the first transistor, wherein the bandgap voltage reference trim circuitry comprises the second transistor.

Example 4 includes the subject matter of any of Examples 1-3, and further including non-volatile memory, wherein the non-volatile memory is to program the programmable circuitry to control an amount of the current provided by the current source that is redirected from the bandgap voltage reference circuitry to the bandgap voltage reference trim circuitry.

Example 5 includes the subject matter of any of Examples 1-4, and wherein the programmable circuitry to redirect some of the current provided by the current source from the bandgap voltage reference circuitry to the bandgap voltage reference trim circuitry comprises a plurality of transistors, wherein the non-volatile memory is to control which of the plurality of transistors are enabled.

Example 6 includes the subject matter of any of Examples 1-5, and further including a switch, wherein an input of the switch is connected to the plurality of transistors, wherein a first output of the switch is connected to a first input of an operational amplifier of the bandgap voltage reference circuitry, wherein a second output of the switch is connected to a resistor, wherein the resistor is connected to a second input of the operational amplifier.

Example 7 includes the subject matter of any of Examples 1-6, and wherein, in use, the switch is to control whether a positive or negative trim is applied to the bandgap voltage reference circuitry.

Example 8 includes an integrated circuit component comprising bandgap voltage reference circuitry comprising a current source; and bandgap voltage reference trim circuitry comprising a plurality of transistors; and control circuitry to control an amount current provided by the current source that is routed through the plurality of transistors.

Example 9 includes the subject matter of Example 8, and further including a current mirror, the current mirror comprising a first transistor and a second transistor, wherein an output of an operational amplifier is connected to a gate of the first transistor and a gate of the second transistor.

Example 10 includes the subject matter of any of Examples 8 and 9, and wherein the bandgap voltage reference circuitry comprises the first transistor, wherein the bandgap voltage reference trim circuitry comprises the second transistor.

Example 11 includes the subject matter of any of Examples 8-10, and further including non-volatile memory, wherein the non-volatile memory is to program the plurality of transistors to control an amount of the current provided by the current source that is redirected from the bandgap voltage reference circuitry to the bandgap voltage reference trim circuitry.

Example 12 includes the subject matter of any of Examples 8-11, and wherein the non-volatile memory is to control which of the plurality of transistors are enabled.

Example 13 includes the subject matter of any of Examples 8-12, and further including a switch, wherein an input of the switch is connected to the plurality of transistors, wherein a first output of the switch is connected to a first input of an operational amplifier of the bandgap voltage reference circuitry, wherein a second output of the switch is connected to a resistor, wherein the resistor is connected to a second input of the operational amplifier.

Example 14 includes the subject matter of any of Examples 8-13, and wherein, in use, the switch is to control whether a positive or negative trim is applied to the bandgap voltage reference circuitry.

Example 15 includes an integrated circuit component comprising bandgap voltage reference circuitry comprising an operational amplifier; a first metal-oxide-semiconductor (MOS) transistor, wherein the first MOS transistor is a P-channel MOS (PMOS) transistor, wherein a gate of the first MOS transistor is connected to an output of the operational amplifier, wherein a source of the first MOS transistor is connected to a voltage source; a second MOS transistor, wherein the second MOS transistor is a PMOS transistor, wherein a source of the second MOS transistor is connected to the voltage source, wherein a gate of the second MOS transistor is connected to the output of the operational amplifier; a third MOS transistor, wherein the third MOS transistor is an N-channel MOS (NMOS) transistor, wherein a drain of the third MOS transistor is connected to a drain of the second MOS transistor, wherein a gate of the third MOS transistor is connected to a drain of the second MOS transistor; and a fourth MOS transistor, wherein the fourth MOS transistor is an NMOS transistor, wherein a drain of the fourth MOS transistor is connected to an input of a switch, wherein a gate of the fourth MOS transistor is connected to a drain of the second MOS transistor.

Example 16 includes the subject matter of Example 15, and further including a current digital to analog converter (DAC), the current DAC comprising a set of MOS transistors, the set of MOS transistors comprising the third MOS transistor and the fourth MOS transistor.

Example 17 includes the subject matter of any of Examples 15 and 16, and further including non-volatile memory, wherein the non-volatile memory is to program the current DAC.

Example 18 includes the subject matter of any of Examples 15-17, and wherein the non-volatile memory is to control which of the set of MOS transistors are enabled.

Example 19 includes the subject matter of any of Examples 15-18, and wherein a first output of the switch is connected to an input of an operational amplifier.

Example 20 includes the subject matter of any of Examples 15-19, and wherein a second output of the switch is connected a resistor, wherein the resistor is connected to a second input of the operational amplifier.

1. An integrated circuit component comprising:
bandgap voltage reference circuitry comprising a current source to provide current; and
bandgap voltage reference trim circuitry comprising programmable circuitry to redirect some of the current provided by the current source from the bandgap voltage reference circuitry to the bandgap voltage reference trim circuitry.

2. The integrated circuit component of claim 1, comprising a current mirror, the current mirror comprising a first transistor and a second transistor, wherein an output of an operational amplifier is connected to a gate of the first transistor and a gate of the second transistor.

3. The integrated circuit component of claim 2, wherein the bandgap voltage reference circuitry comprises the first transistor, wherein the bandgap voltage reference trim circuitry comprises the second transistor.

4. The integrated circuit component of claim 1, further comprising non-volatile memory, wherein the non-volatile memory is to program the programmable circuitry to control an amount of the current provided by the current source that is redirected from the bandgap voltage reference circuitry to the bandgap voltage reference trim circuitry.

5. The integrated circuit component of claim 4, wherein the programmable circuitry to redirect some of the current provided by the current source from the bandgap voltage reference circuitry to the bandgap voltage reference trim circuitry comprises a plurality of transistors, wherein the non-volatile memory is to control which of the plurality of transistors are enabled.

6. The integrated circuit component of claim 5, further comprising a switch,
wherein an input of the switch is connected to the plurality of transistors,
wherein a first output of the switch is connected to a first input of an operational amplifier of the bandgap voltage reference circuitry,
wherein a second output of the switch is connected to a resistor, wherein the resistor is connected to a second input of the operational amplifier.

7. The integrated circuit component of claim 6, wherein, in use, the switch is to control whether a positive or negative trim is applied to the bandgap voltage reference circuitry.

8. An integrated circuit component comprising:
bandgap voltage reference circuitry comprising a current source; and
bandgap voltage reference trim circuitry comprising:
a plurality of transistors; and
control circuitry to control an amount current provided by the current source that is routed through the plurality of transistors.

9. The integrated circuit component of claim 8, comprising a current mirror, the current mirror comprising a first transistor and a second transistor, wherein an output of an operational amplifier is connected to a gate of the first transistor and a gate of the second transistor.

10. The integrated circuit component of claim 9, wherein the bandgap voltage reference circuitry comprises the first transistor, wherein the bandgap voltage reference trim circuitry comprises the second transistor.

11. The integrated circuit component of claim 8, further comprising non-volatile memory, wherein the non-volatile memory is to program the plurality of transistors to control an amount of the current provided by the current source that is redirected from the bandgap voltage reference circuitry to the bandgap voltage reference trim circuitry.

12. The integrated circuit component of claim 11, wherein the non-volatile memory is to control which of the plurality of transistors are enabled.

13. The integrated circuit component of claim 8, further comprising a switch,
wherein an input of the switch is connected to the plurality of transistors,
wherein a first output of the switch is connected to a first input of an operational amplifier of the bandgap voltage reference circuitry,
wherein a second output of the switch is connected to a resistor, wherein the resistor is connected to a second input of the operational amplifier.

14. The integrated circuit component of claim 13, wherein, in use, the switch is to control whether a positive or negative trim is applied to the bandgap voltage reference circuitry.

15. An integrated circuit component comprising:
bandgap voltage reference circuitry comprising:
an operational amplifier;
a first metal-oxide-semiconductor (MOS) transistor, wherein the first MOS transistor is a P-channel MOS (PMOS) transistor, wherein a gate of the first MOS transistor is connected to an output of the operational amplifier, wherein a source of the first MOS transistor is connected to a voltage source;
a second MOS transistor, wherein the second MOS transistor is a PMOS transistor, wherein a source of the second MOS transistor is connected to the voltage source, wherein a gate of the second MOS transistor is connected to the output of the operational amplifier;
a third MOS transistor, wherein the third MOS transistor is an N-channel MOS (NMOS) transistor, wherein a drain of the third MOS transistor is connected to a drain of the second MOS transistor, wherein a gate of the third MOS transistor is connected to a drain of the second MOS transistor; and
a fourth MOS transistor, wherein the fourth MOS transistor is an NMOS transistor, wherein a drain of the fourth MOS transistor is connected to an input of a switch, wherein a gate of the fourth MOS transistor is connected to a drain of the second MOS transistor.

16. The integrated circuit component of claim 15, further comprising a current digital to analog converter (DAC), the current DAC comprising a set of MOS transistors, the set of MOS transistors comprising the third MOS transistor and the fourth MOS transistor.

17. The integrated circuit component of claim 16, further comprising non-volatile memory, wherein the non-volatile memory is to program the current DAC.

18. The integrated circuit component of claim 17, wherein the non-volatile memory is to control which of the set of MOS transistors are enabled.

19. The integrated circuit component of claim 15, wherein a first output of the switch is connected to an input of an operational amplifier.

20. The integrated circuit component of claim 19, wherein a second output of the switch is connected a resistor, wherein the resistor is connected to a second input of the operational amplifier.
